(19) United States
(12) Patent Application Publication
(10) Pub. No.: US 2020/0251657 A1
(43) Pub. Date: Aug. 6, 2020

(54) CONDUCTOR ETCHING FOR PRODUCING THIN-FILM TRANSISTOR DEVICES

(71) Applicant: Flexenable Limited, Cambridge (GB)

(72) Inventors: Jan Jongman, Cambridge (GB); Brian Asplin, Cambridge (GB); Joffrey Dury, Cambridge (GB)

(21) Appl. No.: 16/774,298

(22) Filed: Jan. 28, 2020

(30) Foreign Application Priority Data
Jan. 31, 2019 (GB) 1901359.8

(51) Int. Cl. H01L 51/00; H01L 51/05; H01L 51/10

(52) U.S. Cl. CPC H01L 51/0023; H01L 51/052; H01L 51/0529; H01L 51/055; H01L 51/105; H01L 51/004; H01L 51/0541

(57) ABSTRACT

Method for forming an organic polymer insulator over a first conductor pattern defining a first level of conductors for a thin-film transistor device. A first conductor layer is formed over the organic polymer insulator and a second conductor layer formed over the first conductor layer. The second conductor layer is patterned to define a second level of conductors by exposing the second conductor layer to liquid etchant in selected regions to form a second conductor pattern. The first conductor layer may be located in the selected regions and the first conductor layer and the organic polymer insulator may comprise surface materials that exhibit a substantially zero etch rate for the liquid etchant. The first conductor layer may be less permeable to the liquid etchant than the organic polymer insulator and/or more resistant to damage by the liquid etchant than the organic polymer insulator may be patterned.

### CLAIM OF PRIORITY

This application claims priority to United Kingdom Patent Application No. 1901359.8, filed Jan. 31, 2019, the content of which is hereby incorporated by reference in its entirety.

### FIELD OF THE INVENTION

The production of thin-film transistor (TFT) devices may involve the etching of one or more conductor layers by exposure to a liquid etchant (wet etchant).

The inventors for the present application have conducted research into etching conductor layers over organic polymer layer(s) separating the conductor layer to be etched from a lower conductor pattern.

The inventors for the present application have identified a problem of deterioration of the lower conductor pattern during the etching of upper conductor layers, even when using one or more cross-linked polymer layers for the above-mentioned organic polymer layer(s), which cross-linked polymer layers are characterised by not being soluble in any solvent and having high chemical resistance. The inventors for the present application have attributed the cause of this deterioration to liquid etchant somehow penetrating through the organic polymer layer(s) to the lower conductor pattern, either as a result of damage to the organic polymer layer(s) and/or an inherent permeability of the organic polymer layer(s) for the liquid etchant. The inventors for this application have observed such deterioration of the lower conductor pattern with all the cross-linked polymers they tried for the organic polymer layer(s).

There is hereby provided a method comprising: forming an organic polymer insulator over a first conductor pattern defining a first level of conductors for a thin-film transistor device; forming a first conductor layer over the organic polymer insulator; forming a second conductor layer over the first conductor layer; patterning the second conductor layer by a technique comprising exposing the second conductor layer to liquid etchant in selected regions, to form a second conductor pattern defining a second level of conductors for the thin-film transistor device, wherein: the first conductor layer is at least located in the selected regions; the first conductor layer and the organic polymer insulator comprise surface materials that exhibit a substantially zero etch rate for the liquid etchant; and the first conductor layer is less permeable to the liquid etchant than the organic polymer insulator and/or more resistant to damage by the liquid etchant than the organic polymer insulator; and thereafter patterning the first conductor layer.

According to one embodiment, the first conductor layer extends continuously over the whole area of the first conductor pattern.

According to one embodiment, the surface of the organic polymer insulator comprises a cross-linked polymer layer.

According to one embodiment, the surface material of the organic polymer insulator comprises a cross-linked poly(vinylidenefluoride-trifluoroethylene-chlorotrifluoroethylene terpolymer; and the liquid etchant comprises phosphoric acid and nitric acid.

According to one embodiment, the first and second conductor patterns comprise inorganic metal patterns.

According to one embodiment, the first conductor pattern comprises metallic silver.

According to one embodiment, the first conductor layer comprises an inorganic conductor material.

There is also hereby provided a method comprising: forming an organic polymer insulator over a first conductor pattern defining a first level of conductors for a thin-film transistor device; forming an insulating layer over the insulator; forming a conductor layer over the insulating layer; patterning the conductor layer by a technique comprising exposing the conductor layer to liquid etchant in selected regions to form a second conductor pattern defining a second level of conductors for the thin-film transistor device, wherein: the insulating layer is at least located in the selected regions; the insulating layer and the organic polymer insulator comprise surface materials that exhibit a substantially zero etch rate for the liquid etchant; and the insulating layer is less permeable to the liquid etchant than the organic polymer insulator and/or more resistant to damage by the liquid etchant than the organic polymer insulator.

According to one embodiment, the insulating layer extends continuously over the whole area of the first conductor pattern.

According to one embodiment, the continuous insulating layer exhibits a capacitance of greater than about 20 nF/cm2.

According to one embodiment, the surface of the organic polymer insulator comprises a cross-linked polymer layer.

According to one embodiment, the surface material of the organic polymer insulator comprises a cross-linked poly(vinylidenefluoride-trifluoroethylene-chlorotrifluoroethylene terpolymer; and the liquid etchant comprises phosphoric acid and nitric acid.

According to one embodiment, the first and second conductor patterns comprise inorganic metal patterns.

According to one embodiment, the first conductor pattern comprises metallic silver.

According to one embodiment, the insulating layer comprises an inorganic insulator material.

### BRIEF DESCRIPTION OF THE FIGURES

Embodiments of the present invention are described in detail below, by way of example only, with reference to the accompanying drawings, in which:

FIG. 1 illustrates a first step in a technique according to an example embodiment of the present invention;

FIG. 2 illustrates a second step in a technique according to an example embodiment of the present invention;

FIG. 3 illustrates a third step in a technique according to an example embodiment of the present invention;

FIG. 4 illustrates a fourth step in a technique according to an example embodiment of the present invention;

FIG. 5 illustrates a fifth step in a technique according to an example embodiment of the present invention;

FIG. 6 illustrates a sixth step in a technique according to an example embodiment of the present invention;

FIG. 7 illustrates a seventh step in a technique according to an example embodiment of the present invention;

FIG. 8 illustrates an eighth step in a technique according to an example embodiment of the present invention;

FIGS. 9A and 9B illustrate an advantage of the example embodiment of the present invention;

FIG. 10 illustrates one example alternative to the use of an etchant bath; and

FIG. 11 is a microscopic image showing susceptibility of the organic polymer insulator to damage by the wet etchant.

### DETAILED DESCRIPTION

An example embodiment of the invention is described below for the example of producing an active-matrix array of top-gate thin-film transistors (TFTs) suitable for use in an organic liquid crystal display (OLCD) device; but the same technique is equally applicable to, e.g., the production of the same kind of active-matrix TFT array for other types of display devices, or, e.g., sensor devices; and the production of other types of TFT devices, such as, e.g., an active matrix array of bottom-gate TFTs.

An organic liquid crystal display (OLCD) device comprises an organic transistor device (such as an organic thin film transistor (OTFT) device) for the control component. OTFTs comprise an organic semiconductor (such as, e.g., an organic polymer or small-molecule semiconductor) for the semiconductor channels.

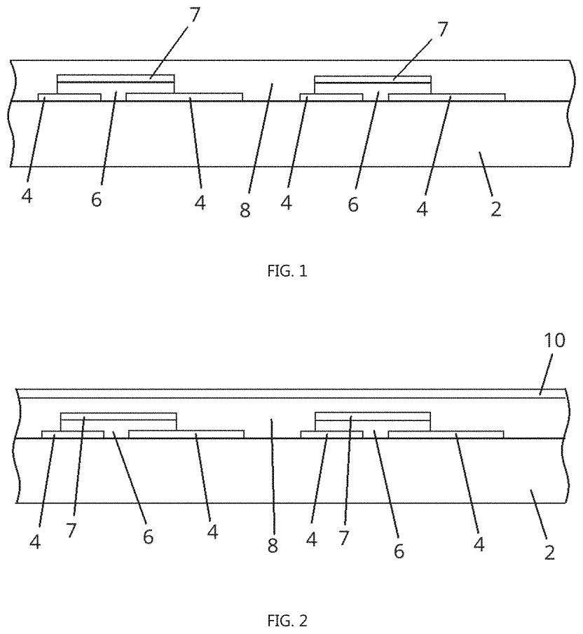

With reference to FIG. 1, the process according to an example embodiment of the present invention begins with a workpiece comprising a substrate 2 and a stack of layers 4, 6, 7, 8 formed in situ on the substrate 2 to define at least a lower conductor pattern 4 and one or more organic polymer insulating layers 8 extending continuously over the lower conductor pattern 4.

In this example, the lower conductor pattern 4 comprises an inorganic metal layer or stack of inorganic metal layers (in this example, a layer comprising metallic silver (Ag) (e.g., Ag—In alloy layer), but other metal/alloy layer(s) may be used) and defines at least the source and drain conductors for a top-gate active matrix TFT array.

In this example, the stack of layers includes: (i) a patterned organic polymer semiconductor layer 6 providing the semiconductor channels for the TFT array; (ii) a patterned organic polymer insulating layer 7, having a pattern substantially matching the pattern of the patterned organic polymer semiconductor layer 6 (which can be achieved by patterning continuous semiconductor and insulating layers using the same etching mask); and (iii) the one or more organic polymer insulating layers 8. The patterned organic polymer insulating layer 7 and one or more organic polymer insulating layers 8 provide the gate dielectric for the TFT array.

In this example, the organic polymer semiconductor pattern 6 and organic polymer insulator pattern 7 are formed in situ on the work-piece by depositing continuous layers of organic polymer semiconductor material and organic polymer insulating material from respective solutions by one or more liquid processing techniques such as spin-coating, followed by patterning the two layers using the same etching mask.

Other semiconductor layers may be used such as, e.g., a metal oxide semiconductor deposited by a liquid processing technique.

In this example, a surface layer of the one or more continuous organic polymer insulating layers 8 is formed in situ on the work-piece by depositing a mixture of a cross-linkable organic polymer material and a cross-linking agent from solution using a liquid processing technique such as e.g. spin-coating, slit coating or flexoprinting, followed by a heat and/or irradiative treatment to initiate the cross-linking. In this example, a cross-linkable polymer material available from Merck under the product code Lisicon® AP048 is deposited and cured (to effect cross-linking), to provide the one or more continuous organic polymer insulating layers 8; and there are at least some regions of the work-piece in which no additional dielectric layer is located between the lower conductor pattern 4 and the ITO layer 10 formed on the cross-linked polymer layer (as mentioned below). Under the same processing conditions (temperature, etching time etc.) as used for the patterning process used to define gate conductors from a metal layer (or stack of metal layers) formed over the cross-linked polymer layer 8, the same cross-linked polymer material is observed to exhibit a substantially zero etch rate with the wet etchant used in said patterning process. In more detail, it has been observed that (under the same processing conditions) a layer of the same cross-linked polymer material exhibits substantially no reduction in surface height (no reduction in thickness) upon exposure to the above-mentioned wet etchant. The ITO layer 10 is not therefore necessary as an etch-stop layer to protect the underlying organic polymer layer 8 from being etched during the process of patterning the upper conductor layer 12; the ITO layer is included in response to the inventor observations of deterioration of the lower conductor pattern below the underlying organic polymer layer 8. As mentioned above, the inventors for the present application attribute this deterioration of the lower conductor pattern 4 to penetration of the etchant down to the lower conductor pattern 4 through the organic insulating polymer layer 8. Based on these observations, the inventors for the present application experimented with including, over the organic insulating polymer layer(s) 8, a layer of an inorganic material (e.g. sputtered ITO layer) that is known to be substantially impermeable and chemically inert to the above-mentioned wet etchant; and found a significant reduction in the deterioration of the underlying lower conductor pattern 4.

There are some regions of the workpiece which: (a) are exposed by the patterning mask 14 mentioned below, and (b) in which the only material between the ITO layer 10 mentioned below and the lower conductor pattern 4 is the above-mentioned organic insulating polymer layer 8 (and/or one or more other organic polymer layers that also are (i) less resistant (more susceptible) than the ITO layer 10 to damage by the wet etchant used to pattern the gate conductor layer, and/or (ii) are more inherently permeable to the wet etchant than the ITO layer 10). The non-uniformities observed in the microscopic image of FIG. 11 reveal damage to the organic insulating polymer when exposed to the wet etchant (under the same processing conditions but without the intervening sputtered ITO layer 10); and the relative resistance of two materials to damage by the wet etchant can be determined from a comparison of microscopic images of layers of the two materials exposed to the wet etchant under the same conditions.

The above description mentions one specific example of a cross-linked polymer material for the one or more organic polymer insulating layers, but other organic polymer dielectric materials may be used including other cross-linked polymer materials and non-cross-linked polymer materials for which the ITO layer 10 is not required as an etch-stop (i.e. which are not etched by the wet etchant used to pattern the gate conductor layer), but may be susceptible to damage by the wet etchant used to pattern the gate conductor layer and/or may be permeable to the wet etchant used to pattern the gate conductor layer. For example, the same benefit has been observed when using a cross-linkable poly(vinylidenefluoride-trifluoroethylene-chlorotrifluoroethylene (VDF-TrFE-CTFE) terpolymer (Solvene® T XL produced by Solvay Speciality Polymers) for the one or more organic polymer insulating layers 8.

The one or more continuous organic polymer insulating layers 8 may be patterned at this stage (by, e.g., dry etching of insoluble and highly chemical-resistant cross-linked polymer material) to provide via holes (not shown) extending down to gate routing conductors (not shown) defined by the lower conductor pattern 4. These via-holes allow for electrical connections between the gate conductors mentioned below and the gate routing conductors.

With reference to FIG. 2, a continuous layer 10 of indium-tin oxide (ITO) is thereafter formed in situ on the upper surface of the workpiece, so as to cover the whole area of the upper surface of the workpiece, including all regions where the lower conductor pattern 4 is located. The ITO layer 10 may be formed by a vapour deposition process such as sputtering.

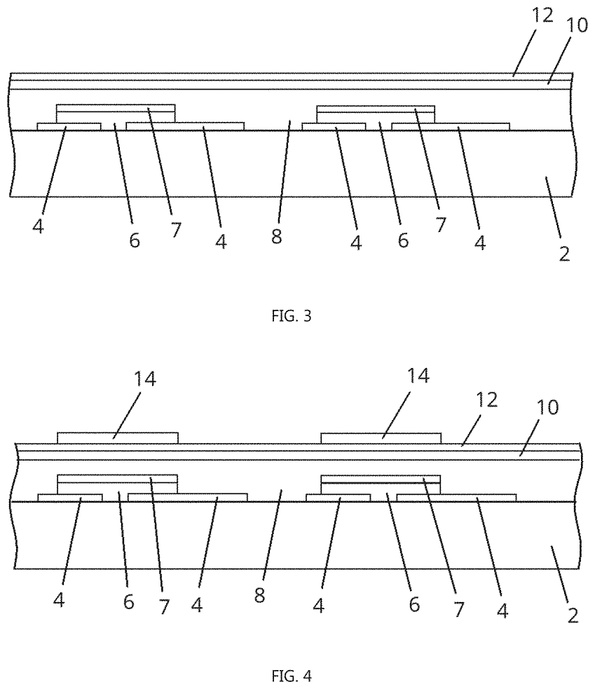

With reference to FIG. 3, a continuous conductor layer 12 (e.g., metal layer or stack of metal sub-layers) is thereafter formed in situ on the upper surface of the workpiece over the ITO layer 10. In this example, a stack of sub-layers comprising an aluminium (Al) layer sandwiched between two molybdenum (Mo) layers is used for the conductor layer 12, but other metal/alloy material(s) may be used; and this continuous conductor layer 12 may, for example, comprise the same metal/alloy material(s) as the lower conductor pattern 4.

With reference to FIG. 4, a patterning mask 14 is thereafter formed on the upper surface of the workpiece. For example, this patterning mask 14 may be formed by a process comprising: forming a layer of photosensitive material in situ on the upper surface of the workpiece over the conductor layer 12; exposing the photosensitive layer to an image (positive or negative, depending on the type of photoresist used) of the desired pattern at a radiation frequency that induces a change in the solubility of the photosensitive material; and developing the latent solubility image.

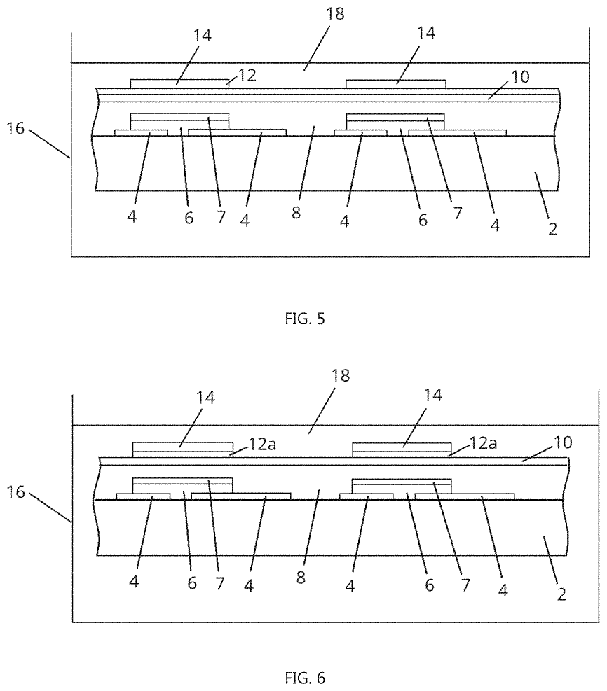

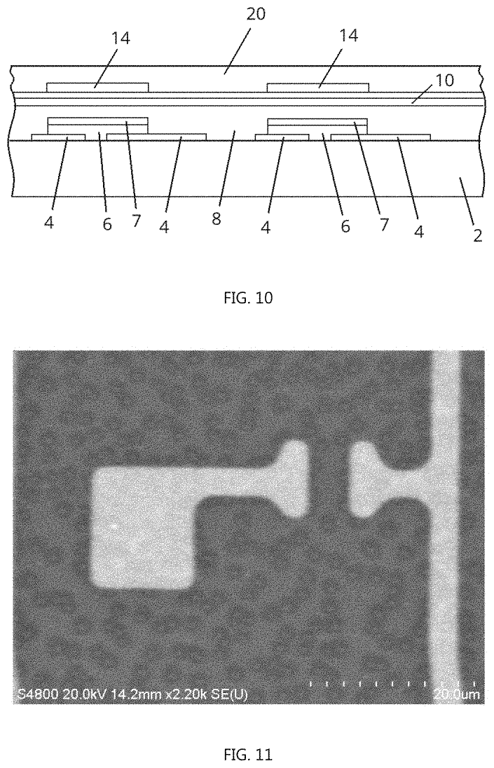

With reference to FIG. 5, the workpiece is thereafter immersed in an etching bath 16 containing liquid etchant 18 such as an acid etchant comprising an aqueous solution comprising nitric acid, phosphoric acid and acetic acid. According to one variation shown in FIG. 10, a film 20 of the liquid etchant is formed on the upper surface of the workpiece by, e.g., spraying.

With reference to FIG. 6, patterning of the conductor layer 12 proceeds by reaction of the acid etchant solution 18 with the conductor layer 12 in the regions exposed by the patterning mask 14, and the dissolution of the products of the reaction into the etchant solution. The upper conductor layer 12 has a relatively high etch rate in the liquid etchant, and after a short period of time determined to be sufficiently long for etching of the entire thickness of the upper conductor layer 12, the workpiece is removed from the etching bath 16 and subjected to a deionised (DI) water rinse to remove residual etchant.

In this example, the conductor pattern 12a remaining after etching defines at least an array of gate conductors for the top-gate active matrix TFT array.

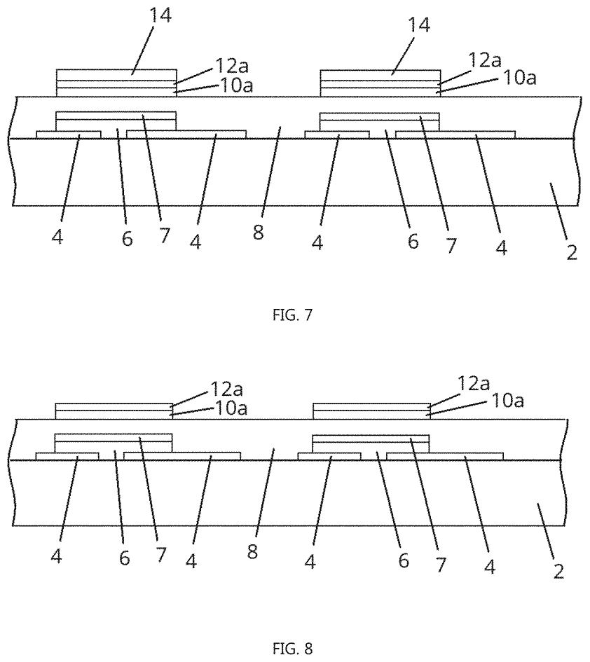

With reference to FIG. 7, the patterning mask 14 remains in place on the upper surface of the workpiece, and is used as the main mask for patterning the ITO layer 10 by dry etching or wet etching (using a liquid etchant to which the lower conductor pattern is resistant, i.e., an etchant in which the material of the lower conductor pattern exhibits a relatively low etch rate (e.g., substantially zero etch rate), compared to the etch rate of the material of the lower conductor pattern in the acid etchant used to pattern the upper conductor layer 12), to create an ITO pattern 10a substantially matching the upper conductor pattern 12.

The patterning mask 14 is thereafter removed, as shown in FIG. 8.

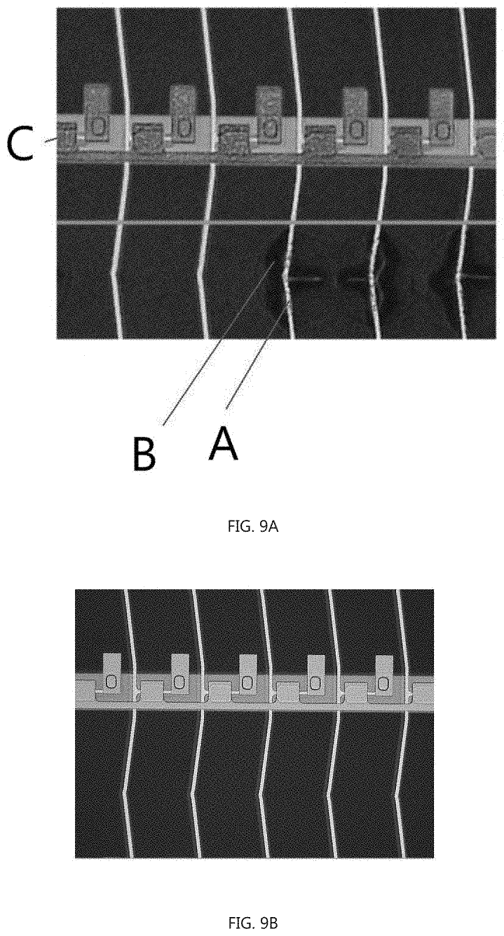

The effect of this example embodiment is clear from a comparison of the microscopic images of FIGS. 9A and 9B, which shows (FIG. 9B) the workpiece after etching, and the result of a comparative experiment (FIG. 9A) which was identical except that the ITO layer 10 was omitted. FIG. 9A (without the ITO layer 10) shows (a) significant deterioration of the lower conductor pattern 4, e.g., deterioration of the source conductor lines in region A; (b) non-uniformities in the cross-linked polymer layer 8 in e.g. region B, which non-uniformities are attributed to the liquid etchant 18 damaging the cross-linked polymer layer 8 and/or permeating into the cross-linked polymer layer 8; and (c) deterioration of the gate conductors in e.g. region C, which deterioration is attributed to permeation of the liquid etchant 18 into and through the cross-linked polymer layer 8. In contrast, none of these are observed in FIG. 9B (with the ITO layer 10). The lower conductor pattern 4 comprises a non-inert metal that is dissolvable in the liquid etchant used to pattern the upper conductor layer 12 (e.g., the materials of the lower conductor pattern 4 and the upper conductor layer 12 may exhibit substantially equally high etch rates in the liquid etchant used to pattern the upper conductor layer 12), but FIG. 9B shows that the ITO layer 10 acts to comprehensively protect the lower conductor pattern 4 from this liquid etchant. As mentioned above, the ITO layer 10 is later patterned using an etchant to which the material of the lower conductor pattern 4 is resistant (i.e. an etchant in which the material of the lower conductor pattern exhibits a relatively low etch rate (e.g., substantially zero etch rate)). Under the same conditions (temperature, etc.), the metal material of the lower conductor pattern 4 is significantly more resistant to dissolution in the etchant used to pattern the ITO layer 10 than it is to dissolution in the liquid etchant used for patterning the upper conductor layer 12. Under the same conditions, the metal material of the lower conductor pattern 4 exhibits a lower etch rate in the ITO etchant than it does in the acid etchant used to pattern the upper conductor layer 12. Also, the underlying organic material 8 in the regions of the device/workpiece exposed by the patterning mask 14 exhibits a substantially zero etch rate with the etchant used to pattern the ITO layer 10.

Under the same conditions, ITO is significantly more resistant to dissolution in the acid etchant solution (used to pattern the upper conductor layer 12) than the metal material of the upper conductor layer 12. Under the same conditions, ITO exhibits a significantly lower etch rate than the metal material of the upper conductor layer 12 for this acid etchant solution (used to pattern the upper conductor layer 12); the ITO layer 10 remains uniformly intact even after 2 minutes exposure to the acid etchant solution, and can thereby function as an effective etch-stop for the patterning of the upper conductor layer 12. The ITO layer 10 is also significantly less permeable to the acid etchant solution than the underlying organic material 8 in the regions of the device exposed by the patterning mask 14, and more resistant to damage by the acid etchant than the underlying organic material 8 in the regions of the device exposed by the patterning mask 14.

Other conductor materials having these two properties may be used instead of ITO. Preferably, the conductor layer 10 has a resistivity R less than about 1 MOhm/square.

The use of a conductor material (such as an conductive inorganic oxide material such as, e.g., ITO) is preferred for the protection layer 10, because it facilitates the formation of a thick protection layer 10 (which is preferred from the point of view of avoiding the penetration of liquid etchant down to the lower conductor pattern 4), without significantly altering the capacitance of the gate dielectric. However, insulating inorganic materials having the above-mentioned good acid etchant resistance and low acid etchant permeability may also be used instead of ITO for the protection layer 10. When using an insulating material for the protection layer 10, the insulating layer preferably exhibits a capacitance of greater than about 20 nF/cm2. One advantage of using an insulating material is that the protection layer 10 does not need patterning in the active area. However, patterning of the insulating protection layer 10 is not excluded, and one example of patterning the insulating protection layer 10 comprises patterning the insulating protection layer 10 outside the active area, before depositing the upper conductor layer as part of a process of forming the above-mentioned vias for conductive connections between the gate conductors and gate routing conductors defined by the lower conductor pattern 4.

Other examples of materials for the protection layer 10 include silicon nitrides, silicon oxides, aluminium nitrides, aluminium oxides, indium gallium zinc oxide (IGZO), indium gallium oxide (IGO) and titanium oxides (TiOx).

Examples of deposition techniques for the protection layer 10 include sputtering, atomic layer deposition (ALD), plasma-enhanced chemical vapour deposition (PECVD) and evaporation.

For the example of producing an OTFT device for an OLCD device, further process steps may include: forming one or more continuous insulating layers over the upper surface of the workpiece; subjecting the workpiece to a patterning process to form via-holes extending down to each drain conductor of the source/drain conductor pattern 4 through the one or more organic polymer layers 8 (e.g., using dry etching of insoluble and highly chemical-resistant cross-linked polymer material); forming a continuous conductor layer over the resulting upper surface of the workpiece, which continuous conductor layer contacts the drain conductors through the via-holes; and patterning the continuous conductor layer to form an array of pixel electrodes, each connected to a respective drain conductor; and other steps depending on the type of OLCD device.

For conciseness, only those elements necessary to explain this example embodiment are shown in FIGS. 1-8, but the stack shown in FIGS. 1-8 may include extra elements. For example, an organic charge injection layer (e.g., a self-assembled monolayer (SAM)) may be provided between the lower conductor pattern 4 and the semiconductor layer 6 to facilitate the transfer of charge carriers between the lower conductor pattern 4 and the semiconductor layer 6. The substrate 2 may, for example, include a plastics support film with a planarisation coating, and may also include one or more additional functional elements.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

What is claimed is:

1. A method comprising:
forming an organic polymer insulator over a first conductor pattern defining a first level of conductors for a thin-film transistor device;
forming a first conductor layer over the organic polymer insulator;
forming a second conductor layer over the first conductor layer; and
patterning the second conductor layer by a technique comprising exposing the second conductor layer to liquid etchant in selected regions, to form a second conductor pattern defining a second level of conductors for the thin-film transistor device, wherein:
the first conductor layer is at least located in the selected regions;
the first conductor layer and the organic polymer insulator comprise surface materials that exhibit a substantially zero etch rate for the liquid etchant; and
the first conductor layer is less permeable to the liquid etchant than the organic polymer insulator and/or more resistant to damage by the liquid etchant than the organic polymer insulator; and
thereafter patterning the first conductor layer.

2. The method according to claim 1, wherein the first conductor layer extends continuously over the whole area of the first conductor pattern.

3. The method according to claim 1, wherein the surface of the organic polymer insulator comprises a cross-linked polymer layer.

4. The method according to claim 3, wherein the surface material of the organic polymer insulator comprises a cross-linked poly(vinylidenefluoride-trifluoroethylene-chlorotrifluoroethylene terpolymer; and the liquid etchant comprises phosphoric acid and nitric acid.

5. The method according to claim 1, wherein the first and second conductor patterns comprise inorganic metal patterns.

6. The method according to claim 5, wherein the first conductor pattern comprises metallic silver.

7. The method according to claim 1, wherein the first conductor layer comprises an inorganic conductor material.

8. A method comprising:
forming an organic polymer insulator over a first conductor pattern defining a first level of conductors for a thin-film transistor device;
forming an insulating layer over the insulator;
forming a conductor layer over the insulating layer; and
patterning the conductor layer by a technique comprising exposing the conductor layer to liquid etchant in selected regions to form a second conductor pattern defining a second level of conductors for the thin-film transistor device, wherein:
the insulating layer is at least located in the selected regions;
the insulating layer and the organic polymer insulator comprise surface materials that exhibit a substantially zero etch rate for the liquid etchant; and
the insulating layer is less permeable to the liquid etchant than the organic polymer insulator and/or more resistant to damage by the liquid etchant than the organic polymer insulator.

9. The method according to claim 8, wherein the insulating layer extends continuously over the whole area of the first conductor pattern.

10. The method according to claim 8, wherein the continuous insulating layer exhibits a capacitance of greater than about 20 nF/cm².

11. The method according to claim 8, wherein the surface of the organic polymer insulator comprises a cross-linked polymer layer.

12. The method according to claim 11, wherein the surface material of the organic polymer insulator comprises a cross-linked poly(vinylidenefluoride-trifluoroethylene-chlorotrifluoroethylene terpolymer; and the liquid etchant comprises phosphoric acid and nitric acid.

13. The method according to claim 8, wherein the first and second conductor patterns comprise inorganic metal patterns.

14. The method according to claim 13, wherein the first conductor pattern comprises metallic silver.

15. The method according to claim 8, wherein the insulating layer comprises an inorganic insulator material.
